(19) United States
(12) Patent Application Publication
(10) Pub. No.: US 2024/0431150 A1
(43) Pub. Date: Dec. 26, 2024

(54) DISPLAY PANEL, DISPLAY APPARATUS, AND METHOD FOR MANUFACTURING DISPLAY PANEL

(71) Applicants: Hefei Visionox Technology Co., Ltd., Hefei (CN); Visionox Technology Inc., Jiangsu (CN)

(72) Inventors: Liusong NI, Hefei (CN); Yiming XIAO, Hefei (CN); Yi-Yu LAI, Hefei (CN); Lipeng GAO, Hefei (CN); Yuan YAO, Hefei (CN); Zhengkui DONG, Hefei (CN); Xuejing ZHU, Hefei (CN); Murong XUE, Hefei (CN); Haohan ZHANG, Hefei (CN); Zihan WANG, Hefei (CN); Zhenhai YUE, Hefei (CN); Bowen YANG, Hefei (CN)

(73) Assignees: Hefei Visionox Technology Co., Ltd., Hefei (CN); Visionox Technology Inc., Jiangsu (CN)

(21) Appl. No.: 18/802,438

(22) Filed: Aug. 13, 2024

Related U.S. Application Data
(63) Continuation of application No. PCT/CN2024/084802, filed on Mar. 29, 2024.

(30) Foreign Application Priority Data
Mar. 31, 2023 (CN) 202310356294.0

(51) Int. Cl. H10K 59/122; H10K 59/12; H10K 59/80

(52) U.S. Cl. CPC H10K 59/122; H10K 59/1201; H10K 59/873

(57) ABSTRACT

The present application relates to a display panel, a display apparatus, and a method for manufacturing a display panel. The display panel includes: a base plate including a pixel definition layer, the pixel definition layer including a plurality of pixel openings, an isolation structure being arranged at a side of the base plate close to the pixel definition layer, and an orthographic projection of the isolation structure on the pixel definition layer being spaced apart from the pixel opening and arranged around the pixel opening; a plurality of sub-pixels; and an encapsulation structure including a plurality of sub-encapsulation portions, the sub-encapsulation portion including a first encapsulation sub-layer and a second encapsulation sub-layer and in a thickness direction of the display panel, an area of an orthographic projection of the second encapsulation sub-layer being less than an area of an orthographic projection of the first encapsulation sub-layer.

### CROSS REFERENCE TO RELATED APPLICATION

This application is a continuation application of International Application No. PCT/CN2024/084802, filed on Mar. 29, 2024, which claims priority to Chinese patent application No. 202310356294.0 filed on Mar. 31, 2023, the entire contents of both of which are incorporated herein by reference.

### TECHNICAL FIELD

The present application relates to the field of display technology, and particularly to a display panel, a display apparatus, and a method for manufacturing a display panel.

### BACKGROUND

Among the current display panels, Organic Light Emitting Diode (OLED) panels are widely used due to their excellent display performance in terms of color, image quality, and the like. When the OLED display panel is manufactured, the structural defect of the existing encapsulation layer may prevent the subsequent filter layer from covering the intended position, resulting in poor display performance for the display panel.

Therefore, there is an urgent need for a display panel that can avoid pixel damage and increase product yield, as well as a corresponding display apparatus and a method for manufacturing the display panel.

### SUMMARY

The present application provides a display panel, a display apparatus, and a method for manufacturing a display panel, and the display panel can avoid pixel electrode damage and increase product yield.

In a first aspect, according to some embodiments of the present application, a display panel is provided. The display panel includes: a base plate including a pixel definition layer, the pixel definition layer including a plurality of pixel openings arranged at intervals, an isolation structure being arranged at a side of the base plate close to the pixel definition layer, and an orthographic projection of the isolation structure on the pixel definition layer being spaced apart from the pixel opening and arranged around the pixel opening; a plurality of sub-pixels arranged in the pixel openings respectively; and an encapsulation structure arranged at a side of the sub-pixel away from the base plate and including a plurality of sub-encapsulation portions, the sub-encapsulation portion being located at a side of the sub-pixel away from the base plate and including a first encapsulation sub-layer and a second encapsulation sub-layer that are stacked, the first encapsulation sub-layer being arranged between the sub-pixel and the second encapsulation sub-layer, and in a thickness direction of the display panel, an area of an orthographic projection of the second encapsulation sub-layer being less than an area of an orthographic projection of the first encapsulation sub-layer.

In a second aspect, according to some embodiments of the present application, a display panel is provided. The display panel includes: a base plate including a pixel definition layer, the pixel definition layer including a plurality of pixel openings arranged at intervals, an isolation structure being arranged at a side of the base plate close to the pixel definition layer, and an orthographic projection of the isolation structure on the pixel definition layer being spaced apart from the pixel opening and arranged around the pixel opening; a plurality of sub-pixels arranged in the pixel openings respectively; and an encapsulation structure arranged at a side of the sub-pixel away from the base plate and including a plurality of sub-encapsulation portions, the sub-encapsulation portion being located at a side of the sub-pixel away from the base plate and including a first encapsulation sub-layer and a second encapsulation sub-layer that are stacked, the first encapsulation sub-layer being arranged between the sub-pixel and the second encapsulation sub-layer, and an etch rate of the second encapsulation sub-layer being greater than an etch rate of the first encapsulation sub-layer.

In a third aspect, according to some embodiments of the present application, a display panel is provided. The display panel includes: a base plate including a pixel definition layer, the pixel definition layer including a plurality of pixel openings arranged at intervals, an isolation structure being arranged at a side of the base plate close to the pixel definition layer, and an orthographic projection of the isolation structure on the pixel definition layer being spaced apart from the pixel opening and arranged around the pixel opening; a plurality of sub-pixels arranged in the pixel openings respectively; and an encapsulation structure arranged at a side of the sub-pixel away from the base plate and including a plurality of sub-encapsulation portions, the sub-encapsulation portion being located at a side of the sub-pixel away from the base plate and including a first encapsulation sub-layer and a second encapsulation sub-layer that are stacked, the first encapsulation sub-layer being arranged between the sub-pixel and the second encapsulation sub-layer, and a density of the second encapsulation sub-layer being less than a density of the first encapsulation sub-layer.

In a fourth aspect, according to some embodiments of the present application, a display panel is provided. The display panel includes: a base plate including a pixel definition layer, the pixel definition layer including a plurality of pixel openings arranged at intervals, an isolation structure being arranged at a side of the base plate close to the pixel definition layer, and an orthographic projection of the isolation structure on the pixel definition layer being spaced apart from the pixel opening and arranged around the pixel opening; a plurality of sub-pixels arranged in the pixel openings respectively; and an encapsulation structure arranged at a side of the sub-pixel away from the base plate and including a plurality of sub-encapsulation portions, the sub-encapsulation portion being located at a side of the sub-pixel away from the base plate and including a first encapsulation sub-layer and a second encapsulation sub-layer that are stacked, the first encapsulation sub-layer being arranged between the sub-pixel and the second encapsulation sub-layer, and a refractive index of the second encapsulation sub-layer being less than a refractive index of the first encapsulation sub-layer.

In a fifth aspect, according to some embodiments of the present application, a display panel is provided. The display panel includes: a base plate including a pixel definition layer, the pixel definition layer including a plurality of pixel openings arranged at intervals, an isolation structure being arranged at a side of the base plate close to the pixel definition layer, and an orthographic projection of the isolation structure on the pixel definition layer being spaced apart from the pixel opening and arranged around the pixel opening; a plurality of sub-pixels arranged in the pixel openings respectively; and an encapsulation structure arranged at a side of the sub-pixel away from the base plate and including a plurality of sub-encapsulation portions, the sub-encapsulation portion being located at a side of the sub-pixel away from the base plate and including a first surface and a second surface arranged oppositely in a thickness direction of the display panel, the first surface being arranged facing the base plate, and in the thickness direction, an area of an orthographic projection of the first surface being greater than an area of an orthographic projection of the second surface.

In a sixth aspect, according to some embodiments of the present application, a display apparatus is provided. The display apparatus includes the display panel according to any of the embodiments in the first aspect to the fifth aspect.

In a seventh aspect, according to some embodiments of the present application, a method for manufacturing a display panel is provided. The method includes: providing a base plate including a pixel definition layer, the pixel definition layer including a plurality of pixel openings arranged at intervals, the pixel openings including a plurality of first openings, and preparing an isolation structure at a side of the pixel definition layer away from the base plate, an orthographic projection of the isolation structure on the pixel definition layer being spaced apart from the pixel opening and arranged around the pixel opening; preparing a first light-emitting material layer and a first electrode layer in sequence in preset one or more of the pixel opening, so as to form a plurality of first sub-pixels in the first openings; forming a first encapsulation layer and a second encapsulation layer in sequence at a side of the first electrode layer away from the base plate; and patterning the first encapsulation layer and the second encapsulation layer to respectively form a first encapsulation sub-layer and a second encapsulation sub-layer, so that an area of an orthographic projection of the second encapsulation sub-layer in a thickness direction of the display panel is less than an area of an orthographic projection of the first encapsulation sub-layer in the thickness direction.

The display panel according to the embodiments of the present application includes the encapsulation structure including a plurality of sub-encapsulation portions arranged corresponding to the sub-pixels, and the sub-encapsulation portion consists of the first encapsulation sub-layer and the second encapsulation sub-layer that are stacked, in which the first encapsulation sub-layer is arranged between the sub-pixel and the second encapsulation sub-layer and has a greater orthographic projection area, so that the sub-encapsulation portion can form a structure that includes a smaller upper portion and a larger lower portion and has a cross-sectional shape approximate to a trapezoid, so as to prevent a chamfered structure formed by the recessed bottom of the encapsulation layer from affecting the subsequent formation of the pixel electrode, and thus the product yield and the reliability of the display panel can be increased.

### BRIEF DESCRIPTION OF THE DRAWINGS

Features, advantages, and technical effects of exemplary embodiments of the present application will be described below with reference to the accompanying drawings.

FIG. 1 shows a schematic structural diagram of a display panel according to an embodiment of the present application;

FIG. 2 shows a schematic structural diagram of a display panel according to another embodiment of the present application;

FIG. 3 shows a schematic structural diagram of a display panel according to yet another embodiment of the present application;

FIG. 4 shows a cross-sectional view at A-A′ illustrated in FIG. 1;

FIG. 5 shows an enlarged view of area P illustrated in FIG. 4;

FIG. 6 shows a schematic cross-sectional structural diagram of a display panel according to an embodiment of the present application;

FIG. 7 shows a schematic structural diagram of a display apparatus according to an embodiment of the present application;

FIG. 8 shows a flowchart of a method for manufacturing a display panel according to an embodiment of the present application;

FIG. 9 shows a schematic structural diagram corresponding to step S1 of the method illustrated in FIG. 8;

FIG. 10 shows a schematic structural diagram corresponding to step S2 of the method illustrated in FIG. 8;

FIG. 11 shows a schematic structural diagram corresponding to step S3 of the method illustrated in FIG. 8;

FIG. 12 shows a schematic structural diagram corresponding to step S4 of the method illustrated in FIG. 8;

FIG. 13 shows a flowchart of a method for manufacturing a display panel according to another embodiment of the present application;

FIG. 14 shows a flowchart of a method for manufacturing a display panel according to yet another embodiment of the present application;

FIG. 15 shows a flowchart of a method for manufacturing a display panel according to yet another embodiment of the present application;

FIG. 16 shows a schematic structural diagram corresponding to step S9 of the method illustrated in FIG. 15.

### DETAILED DESCRIPTION

OLED display panels are widely used due to their excellent display performance. During the manufacturing process, to prevent subsequent pixel processing from affecting the previously prepared pixels, the previously prepared pixels need to be encapsulated first.

From this, the inventors found that the existing encapsulation layer, after being patterned through dry etching, tends to form a structure with a narrower bottom. This prevents the subsequent film layer from covering the intended position, leading to damage to the film layer and poor display performance.

To address these issues, the embodiments of the present application provide a display panel, a display apparatus, and a method for manufacturing a display panel. In the display panel, the shape and the structure of the patterned encapsulation layer are adjusted to ensure that the film layer in subsequent process can successfully cover the preset position, so as to prevent pixel damage and increase the product yield and reliability of the display panel.

The following embodiments of the present application are illustrated merely by taking the effect of the structure of the encapsulation layer on the formation of the pixel electrode as an example, but the embodiments are not limited thereto and can also be applied in other scenarios in which the film layer fails to cover the preset position and require protection for the pixel electrode.

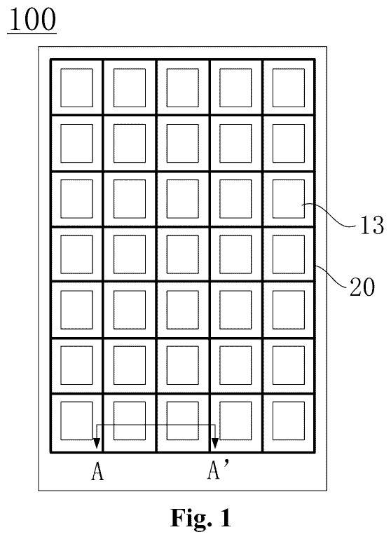

In order to better understand the present application, the display panel, the display apparatus, and the method for manufacturing the display panel according to the embodiments of the present application will be described in detail below in connection with FIGS. 1 to 13.

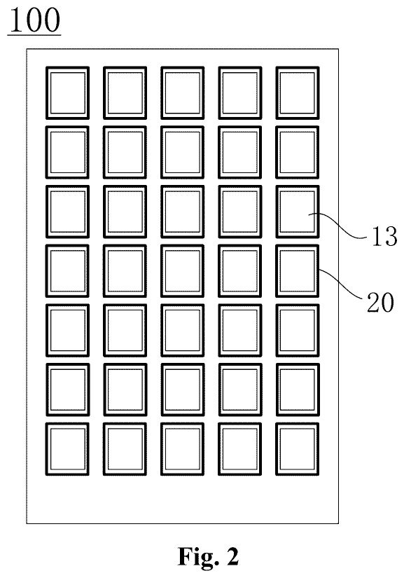

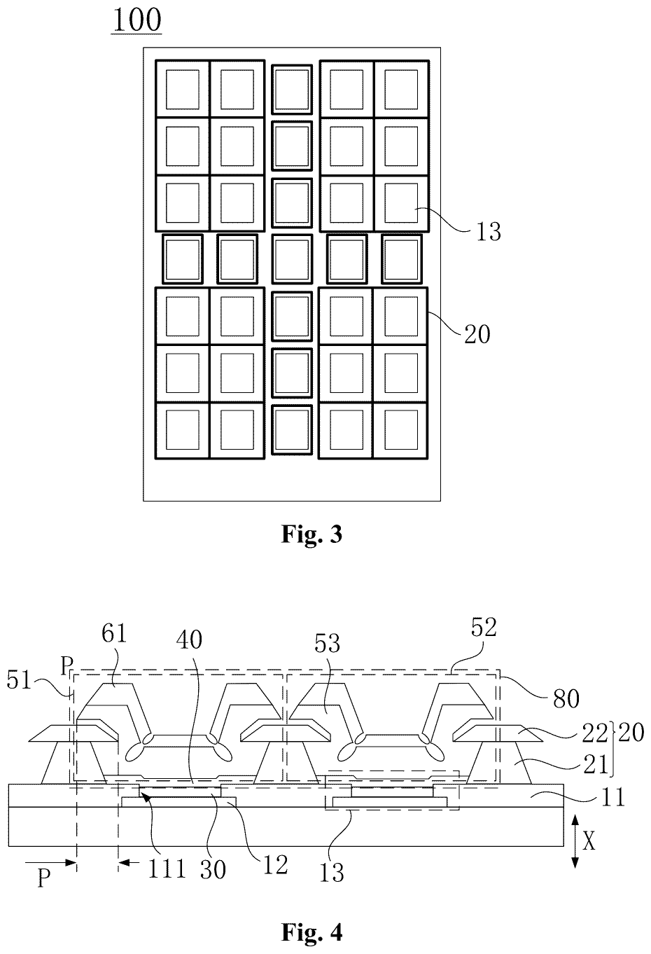

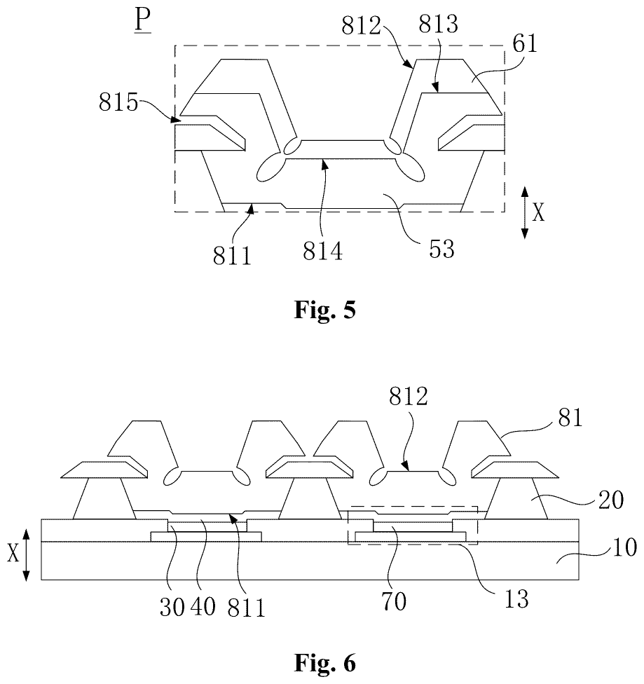

Refer to FIGS. 1 to 5. FIG. 1 shows a schematic structural diagram of a display panel according to an embodiment of the present application. FIG. 2 shows a schematic structural diagram of a display panel according to another embodiment of the present application. FIG. 3 shows a schematic structural diagram of a display panel according to yet another embodiment of the present application. FIG. 4 shows a cross-sectional view at A-A′ illustrated in FIG. 1. FIG. 5 shows an enlarged view of area P illustrated in FIG. 4.

In a first aspect, according to the embodiments of the present application, a display panel 100 is provided. The display panel 100 includes a base plate 10, a plurality of sub-pixels 13, and an encapsulation structure 80. The base plate 10 includes a pixel definition layer 11, the pixel definition layer 11 includes a plurality of pixel openings 111 arranged at intervals, an isolation structure 20 is arranged at a side of the base plate 10 close to the pixel definition layer 11, and an orthographic projection of the isolation structure 20 on the pixel definition layer 11 is spaced apart from the pixel opening 111 and arranged around the pixel opening 111; the plurality of sub-pixels 13 are arranged in the pixel openings 111 respectively; and the encapsulation structure 80 is arranged at a side of the sub-pixel 13 away from the base plate 10 and including a plurality of sub-encapsulation portions 81, the sub-encapsulation portion 81 is located at a side of the sub-pixel 13 away from the base plate 10 and including a first encapsulation sub-layer 53 and a second encapsulation sub-layer 61 that are stacked, the first encapsulation sub-layer 53 is arranged between the sub-pixel 13 and the second encapsulation sub-layer 61, and in a thickness direction X of the display panel 100, an area of an orthographic projection of the second encapsulation sub-layer 61 is less than an area of an orthographic projection of the first encapsulation sub-layer 53.

The embodiments of the present application further provide a display panel 100 which specifically includes a base plate 10, a plurality of sub-pixels 13, and an encapsulation structure 80. The base plate 10 includes a pixel definition layer 11 including a plurality of pixel openings 111, the sub-pixel 13 is arranged in each pixel opening 111, and optionally, the sub-pixels 13 and the pixel openings 111 may be arranged in one-to-one correspondence. Optionally, the base plate 10 may further include one or more layers of other structures, such as a second electrode 12 required for light emitting, in which the second electrode 12 is exposed from the pixel opening 111.

The isolation structure 20 is arranged between the pixel openings 111 and can separate film layers of adjacent sub-pixels 13, forming pixel structures that are independent of each other. This arrangement helps to avoid crosstalk between the adjacent sub-pixels 13 and prevents the spread of oxidation failure caused by water vapor invasion.

Referring to FIG. 4, the isolation structure 20 includes a first isolation portion 21 and a second isolation portion 22, the second isolation portion 22 is located at a side of the first isolation portion 21 away from the base plate 10, and along the thickness direction X of the display panel, an area of an orthographic projection of the second isolation portion 22 is greater than an area of an orthographic projection of the first isolation portion 21. That is, along the thickness direction X of the display panel, the orthographic projection of the first isolation portion 21 is located within an outline of the orthographic projection of the second isolation portion 22. In such cases, the isolation structure 20 forms a bottom-recessed structure that includes a narrower lower layer and a wider upper layer, i.e., an under-cut structure, which facilitates separating the adjacent sub-pixels to avoid crosstalk between the adjacent sub-pixels 13 or spread of oxidation failure caused by water vapor invasion.

The isolation structure 20 in the display panel 100 is arranged around the pixel opening 111. Optionally, as shown in FIG. 1, the isolation structure 20 may be a mesh structure extending continuously along gaps between the pixel openings 111 and is interconnected; or as shown in FIG. 2, the isolation structure 20 may be a ring structure arranged corresponding to the pixel opening 111; or as shown in FIG. 3, both of the above structures may be employed so that the isolation structure 20 is formed as a ring around a plurality of pixel openings 111, and inside the ring, a mesh is formed among the plurality of pixel openings 111.

The encapsulation structure 80 covers a side of the sub-pixel 13 away from the base plate 10 and includes a plurality of sub-encapsulation portions 81, each sub-encapsulation portion 81 includes a first encapsulation sub-layer 53 and a second encapsulation sub-layer 61 that are stacked, the first encapsulation sub-layer 53 is located at a side close to the base plate 10 and has an area greater than the area of the second encapsulation sub-layer 61. Optionally, the sub-encapsulation portion 81 is arranged at a side of the sub-pixel 13 away from the base plate 10 and may be arranged completely covering the corresponding sub-pixel 13, so as to provide encapsulation effect for isolating impurities such as water and oxygen.

With the encapsulation structure 80 forming a structure that includes a narrower upper portion and a wider lower portion, the subsequently vapor deposited layer structure can cover a sidewall of the encapsulation structure 80 completely and reliably during the manufacturing process. This reduces the possibility that the required film layer structure cannot be formed on the sidewall of the encapsulation structure 80, thereby increasing the overall product yield and reliability of the display panel 100.

In some optional embodiments, along the thickness direction X, the orthographic projection of the second encapsulation sub-layer 61 is located within an outline of the orthographic projection of the first encapsulation sub-layer 53.

Optionally, the first encapsulation sub-layer 53 and the second encapsulation sub-layer 61 may be arranged directly opposite each other in the thickness direction X, and the orthographic projection of the first encapsulation sub-layer 53 completely covers the orthographic projection of the second encapsulation sub-layer 61, so as to avoid chamfering in any edge area of the sub-encapsulation portion 81, thereby further increasing the reliability of the display panel 100.

In some optional embodiments, referring to FIGS. 4 and 5, along the thickness direction, the first encapsulation sub-layer 53 includes a first surface 811 close to the base plate 10 and a third surface 813 away from the base plate. Along the thickness direction, an orthographic projection of the third surface 813 is located within an outline of an orthographic projection of the first surface 811. That is, the first encapsulation sub-layer 53 is in a trapezoid-like shape that includes a larger lower portion and a narrower upper portion, the subsequent film layer covers a side edge of the first encapsulation sub-layer 53, and a continuous film layer is formed along the side edge of the first encapsulation sub-layer 53, thereby increasing the overall product yield and reliability of the display panel 100.

In some optional embodiments, referring to FIGS. 4 and 5, along the thickness direction, the second encapsulation sub-layer 61 includes a fourth surface 814 close to the base plate and a second surface 812 away from the base plate. Along the thickness direction, an orthographic projection of the second surface 812 is located within an outline of an orthographic projection of the fourth surface 814. That is, the second encapsulation sub-layer 61 is in a trapezoid-like shape that includes a larger lower portion and a narrower upper portion, the subsequent film layer covers a side edge of the second encapsulation sub-layer 61, and a continuous film layer is formed along the side edge of the second encapsulation sub-layer 61, thereby increasing the overall product yield and reliability of the display panel 100.

Optionally, along the thickness direction, the orthographic projection of the fourth surface 814 is located within an outline of the orthographic projection of the third surface 813, or the outline of the orthographic projection of the fourth surface 814 coincides with the outline of the orthographic projection of the third surface 813. That is, the transition at the joint between the first encapsulation sub-layer 53 and the second encapsulation sub-layer 61 is smooth, and the recess of the sidewall of the sub-encapsulation portion 81 is avoided, so as to prevent the subsequent film layer from being separated or forming crack at the sidewall of the sub-encapsulation portion 81, thereby increasing the overall product yield and reliability of the display panel 100.

In some optional embodiments, along a direction away from the base plate 10, the sub-pixel 13 includes a light-emitting material layer and a first electrode 41 that are stacked on a second electrode 12 in sequence, and the isolation structure 20 is made of a conductor and electrically connected with the first electrode 41.

Optionally, each sub-pixel 13 may include a light-emitting material layer and a first electrode 41 and a second electrode 12 located at two sides of the light-emitting material layer, in which the specific material of the light-emitting material layer may be set according to the required color of the light emitted by the sub-pixel 13, and the electrodes located at two sides may be an anode and a cathode respectively for achieving light emitting after an electrical signal is applied.

Further, the second electrodes 12 may be separated by the pixel definition layer 11 and individually controlled, and the first electrodes 41 may overlap the isolation structure 20 and be electrically connected through the isolation structure 20 made of a conductor, so that a same electrical signal is applied on the first electrodes 41 of a plurality of adjacent sub-pixels 13. For example, the first electrode 41 may be a cathode.

In some optional embodiments, the isolation structure 20 includes a sidewall facing the pixel opening 111, and the sub-encapsulation portion 81 is further arranged to cover the sidewall.

A plurality of pixel openings 111 are formed, protruding from and enclosed by the pixel definition layer 11, and an inner sidewall surface of the isolation structure 20 facing the pixel opening 111 is denoted as the sidewall of the isolation structure 20. The sub-encapsulation portion 81 may be arranged to cover both the side surface of the sub-pixel 13 and the above sidewall, so that the encapsulation is more reliable. Optionally, the sidewall can form a ring around the pixel opening 111, the sub-encapsulation portion 81 may be arranged completely covering the whole sidewall of the ring, and the sub-pixel 13 is encapsulated in a closed space formed by the pixel definition layer 11, the isolation structure 20, and the sub-encapsulation potion 81, which achieves independent encapsulation for the sub-pixel and improves the water and oxygen resistance of the display panel.

In some optional embodiments, the sub-encapsulation portion 81 extends to a side of the isolation structure 20 away from the base plate 10, and in the thickness direction X, an orthographic projection of each sub-encapsulation portion 81 overlaps the orthographic projection of the isolation structure 20, and a width of an overlapping area P is less than a half of a width of the orthographic projection of the isolation structure 20.

The encapsulation structure 80 in the display panel 100 covers the side of the sub-pixel 13 away from the base plate 10. The encapsulation structure 80 may include a plurality of sub-encapsulation portions 81 arranged corresponding to the sub-pixels 13. The main body of the sub-encapsulation portion 81 is arranged in the pixel opening 111 and extends from the pixel opening 111 to the isolation structure 20 around the opening and covers at least a portion of the sidewall and a portion of the top wall of the isolation structure 20. A portion of the sub-encapsulation portion covering the top wall of the isolation structure 20 covers only a portion of the wall surface.

Specifically, in the thickness direction X of the display panel 100, the orthographic projection of each sub-encapsulation portion overlaps the orthographic projection of the isolation structure 20 with an overlapping area P, while a width of the overlapping area P should be less than or equal to a half of the width of the orthographic projection of the isolation structure 20. Optionally, the above width refers to an extension dimension in a direction which is parallel to the base plate 10 and perpendicular to the extension direction of the isolation structure 20. The extension direction of the isolation structure 20 refers to an extension direction of a portion of the isolation structure 20 sandwiched between two sub-pixels 13 arranged corresponding to adjacent sub-encapsulation portions.

Exemplarily, in an embodiment in which the sub-encapsulation portions 81 are arranged at both sides of a certain segment of isolation structure 20 in a direction perpendicular to the extension direction of the segment of isolation structure 20, the sub-encapsulation portions 81 at both sides respectively extend to the top surface of the isolation structure 20 and respectively cover a portion of the top surface, and the two sub-encapsulation portions 81 may be spaced apart from each other or connected with each other.

In some optional embodiments, the sub-encapsulation portion 81 further extends to a side of the isolation structure 20 away from the base plate 10 and forms a gap 815 with a surface of the isolation structure 20 away from the base plate 10. In such cases, the sub-encapsulation portions 81 corresponding to the adjacent sub-pixels 13 are also separated from each other at the side of the isolation structure 20 away from the base plate 10. That is, the adjacent sub-encapsulation portions 81 are spaced apart from each other at the side of the isolation structure 20 away from the base plate 10, and thus the path for water vapor to flow between the adjacent sub-pixels 13 is cut off and the encapsulation performance of the display panel is improved.

By adjusting the structure and the position of each sub-encapsulation portion 81 during the manufacturing process of the display panel 100, a film layer formed in subsequent processes after the formation of at least a portion of the sub-encapsulation portion 81 can successfully cover the preset area, thereby increasing the overall processing accuracy and reliability of the display panel 100.

In some optional embodiments, a thickness of the first encapsulation sub-layer 53 is greater than a thickness of the second encapsulation sub-layer 61. By adjusting the thicknesses of the two encapsulation sub-layers, the first encapsulation sub-layer 53 located at a lower layer has a relatively greater thickness, so that when forming the encapsulation sub-portion by patterning, the desired trapezoid-like structure is formed more quickly.

In some optional embodiments, an etch rate of the second encapsulation sub-layer 61 is greater than an etch rate of the first encapsulation sub-layer 53.

In some optional embodiments, a density of the second encapsulation sub-layer 61 is less than a density of the first encapsulation sub-layer 53.

In some optional embodiments, a refractive index of the second encapsulation sub-layer 61 is less than a refractive index of the first encapsulation sub-layer 53.

Optionally, in order to enable the display panel 100 to be easily manufactured while maintaining the relative size relationship between the first encapsulation sub-layer 53 and the second encapsulation sub-layer 61, the parameters of the two encapsulation sub-layers may be adjusted so that they can be prepared simultaneously in a same process. For example, the second encapsulation sub-layer 61 may have higher etch efficiency during etching, or the second encapsulation sub-layer 61 may have a looser film layer structure, or the second encapsulation sub-layer 61 may have a lower refractive index, and so on. In either way, the second encapsulation sub-layer 61 can have, after being prepared, a less orthographic projection area with respective to the first encapsulation sub-layer 53.

In a second aspect, according to the embodiments of the present application, a display panel 100 is provided. The display panel 100 includes: a base plate 10 including a pixel definition layer 11, the pixel definition layer 11 including a plurality of pixel openings 111 arranged at intervals, an isolation structure 20 being arranged at a side of the base plate 10 close to the pixel definition layer 11, and an orthographic projection of the isolation structure 20 on the pixel definition layer 11 being spaced apart from the pixel opening 111 and arranged around the pixel opening 111; a plurality of sub-pixels 13 arranged in the pixel openings 111 respectively; and an encapsulation structure 80 arranged at a side of the sub-pixel 13 away from the base plate 10 and including a plurality of sub-encapsulation portions 81, the sub-encapsulation portion 81 being located at a side of the sub-pixel 13 away from the base plate 10 and including a first encapsulation sub-layer 53 and a second encapsulation sub-layer 61 that are stacked, the first encapsulation sub-layer 53 being arranged between the sub-pixel 13 and the second encapsulation sub-layer 61, and an etch rate of the second encapsulation sub-layer 61 being greater than an etch rate of the first encapsulation sub-layer 53.

In some optional embodiments, in a thickness direction X of the display panel 100, an area of an orthographic projection of the second encapsulation sub-layer 61 is less than an area of an orthographic projection of the first encapsulation sub-layer 53.

In some optional embodiments, a density of the second encapsulation sub-layer 61 is less than a density of the first encapsulation sub-layer 53.

In some optional embodiments, a refractive index of the second encapsulation sub-layer 61 is less than a refractive index of the first encapsulation sub-layer 53.

In a third aspect, according to the embodiments of the present application, a display panel 100 is provided. The display panel 100 includes: a base plate 10 including a pixel definition layer 11, the pixel definition layer 11 including a plurality of pixel openings 111 arranged at intervals, an isolation structure 20 being arranged at a side of the base plate 10 close to the pixel definition layer 11, and an orthographic projection of the isolation structure 20 on the pixel definition layer 11 being spaced apart from the pixel opening 111 and arranged around the pixel opening 111; a plurality of sub-pixels 13 arranged in the pixel openings 111 respectively; and an encapsulation structure 80 arranged at a side of the sub-pixel 13 away from the base plate 10 and including a plurality of sub-encapsulation portions 81, the sub-encapsulation portion 81 being located at a side of the sub-pixel 13 away from the base plate 10 and including a first encapsulation sub-layer 53 and a second encapsulation sub-layer 61 that are stacked, the first encapsulation sub-layer 53 being arranged between the sub-pixel 13 and the second encapsulation sub-layer 61, and a density of the second encapsulation sub-layer 61 being less than a density of the first encapsulation sub-layer 53.

In some optional embodiments, in a thickness direction X of the display panel 100, an area of an orthographic projection of the second encapsulation sub-layer 61 is less than an area of an orthographic projection of the first encapsulation sub-layer 53.

In some optional embodiments, an etch rate of the second encapsulation sub-layer 61 is greater than an etch rate of the first encapsulation sub-layer 53.

In some optional embodiments, a refractive index of the second encapsulation sub-layer 61 is less than a refractive index of the first encapsulation sub-layer 53.

In a fourth aspect, according to the embodiments of the present application, a display panel is provided. The display panel includes: a base plate 10 including a pixel definition layer 11, the pixel definition layer 11 including a plurality of pixel openings 111 arranged at intervals, an isolation structure 20 being arranged at a side of the base plate 10 close to the pixel definition layer 11, and an orthographic projection of the isolation structure 20 on the pixel definition layer 11 being spaced apart from the pixel opening 111 and arranged around the pixel opening 111; a plurality of sub-pixels 13 arranged in the pixel openings 111 respectively; and an encapsulation structure 80 arranged at a side of the sub-pixel 13 away from the base plate 10 and including a plurality of sub-encapsulation portions 81, the sub-encapsulation portion 81 being located at a side of the sub-pixel 13 away from the base plate 10 and including a first encapsulation sub-layer 53 and a second encapsulation sub-layer 61 that are stacked, the first encapsulation sub-layer 53 being arranged between the sub-pixel 13 and the second encapsulation sub-layer 61, and a refractive index of the second encapsulation sub-layer 61 being less than a refractive index of the first encapsulation sub-layer 53.

In some optional embodiments, in a thickness direction X of the display panel 100, an area of an orthographic projection of the second encapsulation sub-layer 61 is less than an area of an orthographic projection of the first encapsulation sub-layer 53.

In some optional embodiments, an etch rate of the second encapsulation sub-layer 61 is greater than an etch rate of the first encapsulation sub-layer 53.

In some optional embodiments, a density of the second encapsulation sub-layer 61 is less than a density of the first encapsulation sub-layer 53.

Referring to FIG. 6, FIG. 6 shows a schematic cross-sectional structural diagram of a display panel according to an embodiment of the present application. In a fifth aspect, according to the embodiments of the present application, a display panel 100 is provided. The display panel 100 includes: a base plate 10 including a pixel definition layer 11, the pixel definition layer 11 including a plurality of pixel openings 111 arranged at intervals, an isolation structure 20 being arranged at a side of the base plate 10 close to the pixel definition layer 11, and an orthographic projection of the isolation structure 20 on the pixel definition layer 11 being spaced apart from the pixel opening 111 and arranged around the pixel opening 111; a plurality of sub-pixels 13 arranged in the pixel openings 111 respectively; and an encapsulation structure 80 arranged at a side of the sub-pixel 13 away from the base plate 10 and including a plurality of sub-encapsulation portions 81, the sub-encapsulation portion 81 being located at a side of the sub-pixel 13 away from the base plate 10 and including a first surface 811 and a second surface 812 arranged oppositely in a thickness direction X of the display panel 100, the first surface 811 being arranged facing the base plate 10, and in the thickness direction X, an area of an orthographic projection of the first surface 811 being greater than an area of an orthographic projection of the second surface 812.

The display panel 100 includes the encapsulation structure 80, the encapsulation structure 80 includes a plurality of sub-encapsulation portions 81 corresponding to the sub-pixels 13 and arranged covering the sub-pixels 13, and each sub-encapsulation portion 81 includes the first surface 811 arranged facing the base plate 10 and the second surface 812 away from the base plate 10, in which the first surface 811 has a greater orthographic projection area, i.e., an upper surface of the sub-encapsulation portion 81 has a less orthographic projection area, so that a trapezoid structure that includes a narrower upper portion and a wider lower portion can be formed, and thus the film layer can completely cover the side edge of the sub-encapsulation portion 81.

Optionally, in the thickness direction X, the orthographic projection of the second surface 812 may be located within an outline of the orthographic projection of the first surface 811. Optionally, since the isolation structure 20 is protruding, the sub-encapsulation 81 may have a non-flat upper surface, and thus the actual area of the upper surface of the sub-encapsulation 81 may be greater than or equal to the actual area of the lower surface, as long as the orthographic projection of the upper surface in the thickness direction X is less than that of the lower surface.

In some optional embodiments, the sub-encapsulation portion 81 includes a first encapsulation sub-layer 53 and a second encapsulation sub-layer 61 that are stacked, the first encapsulation sub-layer 53 is arranged between the sub-pixel 13 and the second encapsulation sub-layer 61, and the first surface and the second surface are respectively arranged at a side of the first encapsulation sub-layer 53 away from the second encapsulation sub-layer 61 and a side of the second encapsulation sub-layer 61 away from the first encapsulation sub-layer 53.

The sub-encapsulation portion 81 may consist of two layers of structures, e.g., including the first encapsulation sub-layer 53 and the second encapsulation sub-layer 61 that are stacked in sequence, and the first encapsulation sub-layer 53 is in direct contact with the second encapsulation sub-layer 61.

Herein, in the thickness direction of the display panel, an area of an orthographic projection of the second encapsulation sub-layer 61 is less than an area of an orthographic projection of the first encapsulation sub-layer 53, so that the sub-encapsulation portion forms a trapezoid-like structure that includes a smaller upper portion and a larger lower portion.

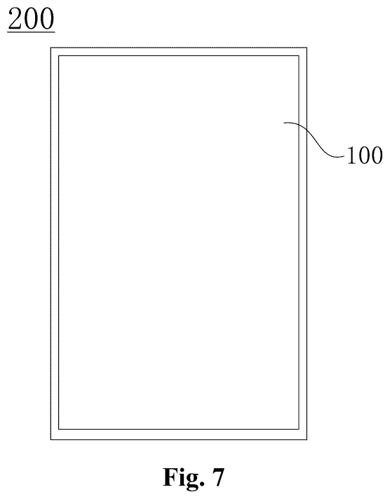

Referring to FIG. 7, FIG. 7 shows a schematic structural diagram of a display apparatus according to an embodiment of the present application. In a sixth aspect, according to the embodiments of the present application, a display apparatus 200 is provided. The display apparatus 200 includes the display panel 100 according to any of the embodiments in the first aspect to the fifth aspect.

The display apparatus 200 according to the embodiments of the present application includes the display panel 100 according to any of the above embodiments, and the display apparatus 200 may be a mobile phone, a tablet computer, a digital photo frame, an electronic paper, and any other products or components having a display function. The display apparatus 200 according to the embodiments of the present application has the beneficial effects of the display panel 100 according to the embodiments of the present application, and reference is made to the specific description of the display panel 100 in the above embodiments, which will not be repeated herein.

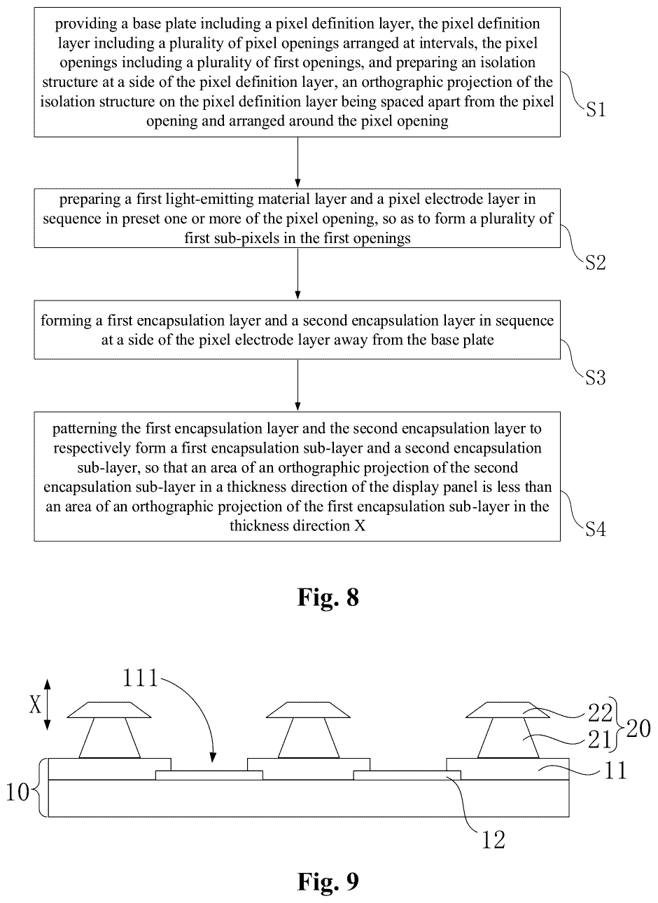

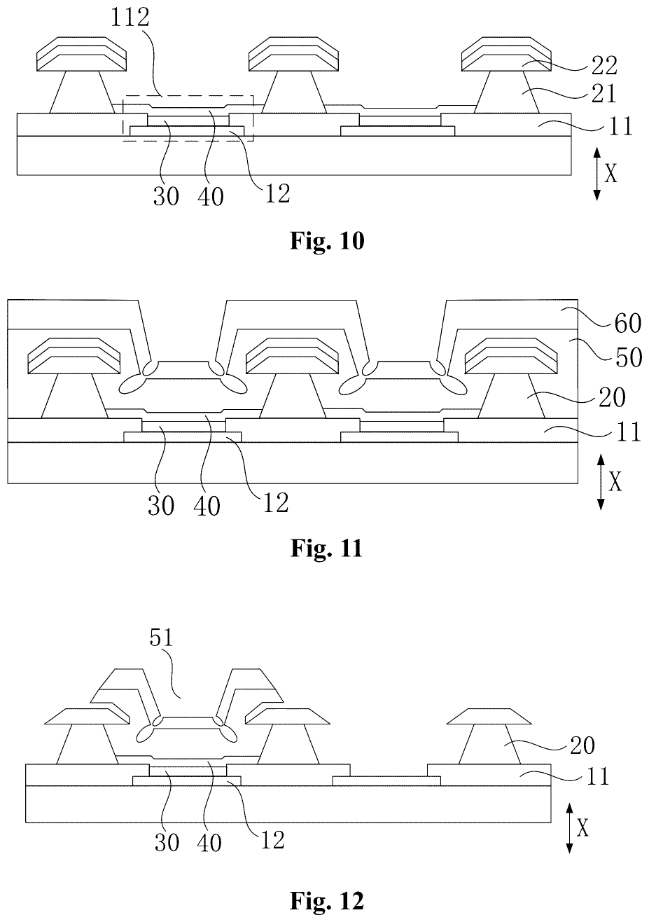

Referring to FIGS. 8 to 12, FIG. 8 shows a flowchart of a method for manufacturing a display panel according to an embodiment of the present application, FIG. 9 shows a schematic structural diagram corresponding to step S1 of the method illustrated in FIG. 8, FIG. 10 shows a schematic structural diagram corresponding to step S2 of the method illustrated in FIG. 8, FIG. 11 shows a schematic structural diagram corresponding to step S3 of the method illustrated in FIG. 8, and FIG. 12 shows a schematic structural diagram corresponding to step S4 of the method illustrated in FIG. 8.

In a seventh aspect, according to the embodiments of the present application, a method for manufacturing a display panel 100 is provided. The method includes:
S1: providing a base plate 10 including a pixel definition layer 11, the pixel definition layer 11 including a plurality of pixel openings 111 arranged at intervals, the pixel openings 111 including a plurality of first openings, and preparing an isolation structure 20 at a side of the pixel definition layer 11 away from the base plate 10, an orthographic projection of the isolation structure 20 on the pixel definition layer 11 being spaced apart from the pixel opening 111 and arranged around the pixel opening 111;
S2: preparing a first light-emitting material layer 30 and a first electrode layer 40 in sequence in preset one or more of the pixel opening 111, so as to form a plurality of first sub-pixels 112 in the first openings;
S3: forming a first encapsulation layer 50 and a second encapsulation layer 60 in sequence at a side of the first electrode layer 40 away from the base plate 10; and
S4: patterning the first encapsulation layer 50 and the second encapsulation layer 60 to respectively form a first encapsulation sub-layer 53 and a second encapsulation sub-layer 61, so that an area of an orthographic projection of the second encapsulation sub-layer 61 in a thickness direction X of the display panel 100 is less than an area of an orthographic projection of the first encapsulation sub-layer 53 in the thickness direction X.

The embodiments of the present application provide a method for manufacturing a display panel 100, which firstly includes step S1, i.e., providing the base plate 10 and preparing the isolation structure 20 on the base plate 10. Specifically, the base plate 10 includes the pixel definition layer 11, a plurality of pixel openings 111 are arranged at intervals in the pixel definition layer 11, and the pixel openings 111 correspond to the positions configured to define of the pixels to be prepared, in which the pixel openings 111 configured to set a same certain color may be defined as the first openings according to the color of the light emitted by each sub-pixel 13 in the display panel 100. In addition to the pixel definition layer 11, the base plate 10 may further include one or more layers of other structures, which may include corresponding circuit wiring configured to be electrically connected with the pixel and control the pixel to emit light, and the like. Optionally, a second electrode 12 required for forming the pixel may be arranged corresponding to the pixel opening 111 in the base plate 10, and the second electrode 12 is at least partially exposed from the pixel opening 111, forming the light-emitting pixel with the subsequent light-emitting material and another electrode, etc.

In step S1, the isolation structure 20 is prepared on the pixel definition layer 11, the isolation structure 20 is spaced apart from the pixel opening 111 and arranged around the pixel opening 111. That is, the isolation structure 20 is arranged between adjacent pixels to be formed, and may be configured to separate film layers of the adjacent pixels and form pixel structures that are independent of each other, so as to avoid crosstalk between the adjacent pixels or spread of oxidation failure caused by water vapor invasion.

In step S2, at the same side of the base plate 10, i.e., the side at which the isolation structure 20 is arranged, the first light-emitting material layer 30 and the first electrode layer 40 are prepared in sequence, so that the first light-emitting material layer 30 and the first electrode layer 40 form a stacked structure at least at a position corresponding to the first pixel opening, and may form, together with the above second electrode 12, a first sub-pixel 112 in which the light-emitting material layer is sandwiched between the metal electrodes located at two sides, so as to achieve display. When the first light-emitting material layer 30 and the first electrode layer 40 are prepared, vapor deposition and the like may be used, and the first light-emitting material layer 30 may include a light-emitting material required for pixels of a certain same color in the display panel 100, such as any one of red, green, and blue, and any suitable color may be selected.

Optionally, the second electrode 12 may be an anode, while the electrode formed by the first electrode layer 40 may correspondingly be a cathode. In such case, the cathode formed by the first electrode layer 40 needs to be electrically connected with a power supply. In an optional implementation, the cathode formed by the first electrode layer 40 is extended to overlap the peripheral isolation structure 20, so as to achieve electrical connection. In an embodiment in which an electrically conductive material is used at the position of the isolation structure 20 overlapping the cathode, a path may be formed between the cathodes of the adjacent sub-pixels through the isolation structure 20 arranged around the sub-pixels, and thus an area electrode covering a plurality of sub-pixels or a planar electrode arranged as a whole is formed, which facilitates electrical connection with a power supply located at the periphery of the display panel, so as to achieve the overall control of the cathodes.

In step S3, firstly, the first encapsulation layer 50 and the second encapsulation layer 60 are formed in sequence at the side of the first electrode layer 40 away from the base plate 10, and the two encapsulation layers are stacked and cover the above first electrode layer 40, so as to encapsulate the light-emitting pixel.

In step S4, the above two encapsulation layers need to be patterned to form an encapsulation structure corresponding to the above first sub-pixel 112, and the patterning may be achieved by photolithography and the like. Specifically, in the process of patterning the first encapsulation layer 50 and the second encapsulation layer 60, the processing method should be adjusted accordingly, so that after the patterning, an area of an orthographic projection of the second encapsulation layer 60 in the thickness direction X is less than an area of an orthographic projection of the first encapsulation layer 50 in the direction. That is, in the process of patterning, a larger area of the second encapsulation layer 60 should be removed, so as to form a trapezoid-like structure in which the second encapsulation layer 60 located at the upper layer is smaller and the first encapsulation layer 50 located at the lower layer is larger.

On this basis, the etch difference between the first encapsulation layer 50 and the second encapsulation layer 60 may be achieved by multiple etchings, adjusting the material of the encapsulation layer, and the like, and any suitable processing method may be used. After the patterning, the two encapsulation layers that are stacked can form, at the position corresponding to the first sub-pixel 112, a structure that includes a narrower upper layer and a wider lower layer, and thus the effect of the recess caused by etching on subsequent vapor deposition or deposition of other film layers can be avoided, which ensures that the layer structures, such as the first electrode layer, formed during the remaining processing of the pixels can completely cover the preset area at the periphery of the encapsulation layer.

Specifically, the etch difference between the first encapsulation layer 50 and the second encapsulation layer 60 may be obtained by multiple etchings. For example, in step S4 of patterning the two encapsulation layers, the second encapsulation layer 60 may be etched first, the portions corresponding to the areas except the first sub-pixel 112 are removed, and then the first encapsulation layer 50 is etched, that is, the first encapsulation layer 50 is etched through the opening generated by the previous etching in the second encapsulation layer 60, so as to obtain a double-layer encapsulation structure with a desired shape.

Alternatively, step S3 and step S4 may be performed in reverse order. That is, the first encapsulation layer 50 is prepared and patterned firstly, then the second encapsulation layer 60 is prepared on the patterned first encapsulation layer 50, and finally the second encapsulation layer 60 is patterned. By adjusting the exposure dose or the photolithography mask pattern in the two patterning processes, a double-layer encapsulation structure with a desired shape is obtained.

In order to reduce the requirement for processing accuracy of the patterning, the first encapsulation layer 50 and the second encapsulation layer 60 may be processed by synchronized etching. With the first encapsulation layer 50 and the second encapsulation layer 60 being arranged to be made of different materials or having structures with different densities, the first encapsulation layer 50 and the second encapsulation layer 60 may have different etch rates, which allows for the formation of the second encapsulation layer 60 and the first encapsulation layer 50 with different widths in a same etching process.

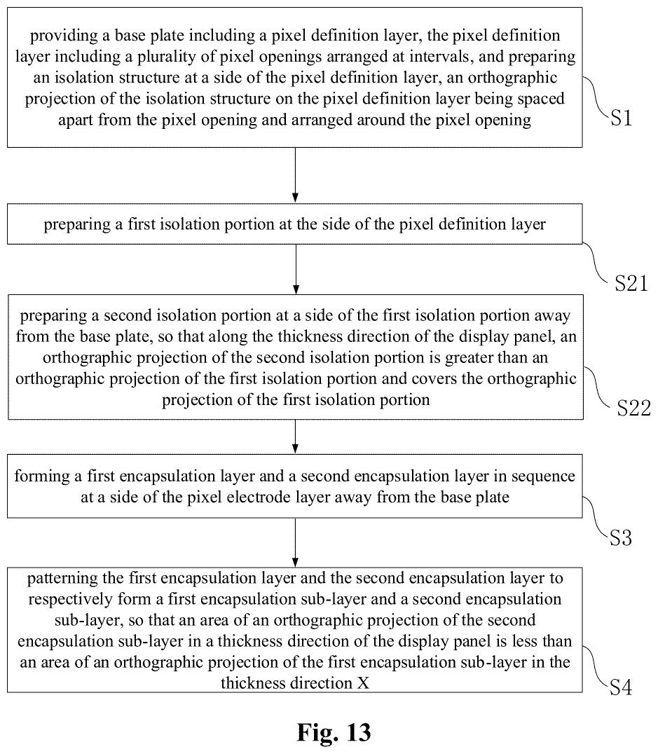

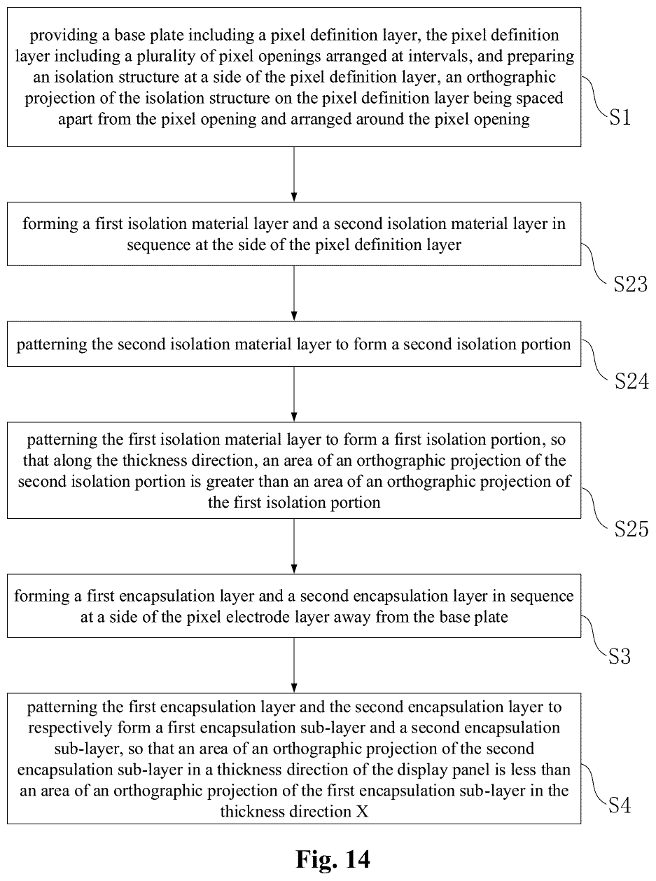

Referring to FIGS. 13 and 14 together, FIG. 13 shows a flowchart of a method for manufacturing a display panel according to another embodiment of the present application, and FIG. 14 shows a flowchart of a method for manufacturing a display panel according to yet another embodiment of the present application. In some optional embodiments, the step S2 of preparing the isolation structure 20 at the side of the pixel definition layer 11 includes:
S21: preparing a first isolation portion 21 at the side of the pixel definition layer 11; and
S22: preparing a second isolation portion 22 at a side of the first isolation portion 21 away from the base plate 10, so that along the thickness direction X of the display panel 100, an area of an orthographic projection of the second isolation portion 22 is greater than an area of an orthographic projection of the first isolation portion 21, and the orthographic projection of the second isolation portion 22 covers the orthographic projection of the first isolation portion 21.

Alternatively, the step S2 of preparing the isolation structure 20 at the side of the pixel definition layer 11 includes:
S23: forming a first isolation material layer and a second isolation material layer in sequence at the side of the pixel definition layer;
S24: patterning the second isolation material layer to form a second isolation portion 22; and
S25: patterning the first isolation material layer to form a first isolation portion 21, so that along the thickness direction X, an area of an orthographic projection of the second isolation portion 22 is greater than an area of an orthographic projection of the first isolation portion 21.

The method for manufacturing the display panel 100 according to the embodiments of the present application includes preparing the isolation structure 20 on the base plate 10, so as to separate the film layer structures of the adjacent pixels and arrange the pixels independently. On this basis, the step S2 of preparing the isolation structure 20 may include the step S21 of preparing the first isolation portion 21 and the step S22 of preparing the second isolation portion 22. That is, the obtained isolation structure 20 includes two portions that are stacked, the first isolation portion 21 is arranged between the second isolation portion 22 and the base plate 10, and in the thickness direction X, the area of the orthographic projection of the first isolation portion 21 is less than the area of the orthographic projection of the second isolation portion 22. In such cases, the isolation structure 20 forms a bottom-recessed structure that includes a narrower lower layer and a wider upper layer, i.e., an under-cut structure.

The isolation structure 20 in the embodiments of the present application is arranged in the gaps between adjacent pixels and has an under-cut structure with a recessed bottom, so that when other film layer structures are prepared on the isolation structure 20, the under-cut structure enables the film layer to be automatically separated at the position where the isolation structure 20 is located, so as to form a plurality of structures that are independent of each other and arranged corresponding to the pixel openings 111 surrounded by the isolation structure 20. Consequently, in the process steps after the preparation of the isolation structure 20, a Fine Metal Mask (FMM) may be omitted in the vapor deposition process, while the isolation structure 20 is used to separate the film layer structure, and thus the processing cost can be effectively reduced.

As described above, after the first sub-pixel 112 being formed, the periphery of the first electrode layer 40 located in the upper layer may be connected with the first isolation portion 21. In such cases, the electrically conductive performance of the isolation structure 20, especially the first isolation portion 21, may be adjusted to achieve the electrical connection between adjacent first electrodes 41. For example, the first isolation portion 21 may be arranged as a metal material that is electrically conductive to achieve a whole-surface arrangement for the pixel electrodes, or the first isolation portion 21 may be arranged as an insulating structure to make the pixels to be independent of each other, so as to cooperate with other wirings to control the pixels independently, etc. Any suitable method may be used, and may be selected according to use and processing conditions.

Optionally, when the isolation structure 20 is processed, the first isolation portion 21 and the second isolation portion 22 may be processed in sequence. That is, the first isolation material layer is prepared and patterned to obtain the first isolation portion 21, and then the second isolation material layer is prepared and patterned to obtain the second isolation portion 22. Alternatively, the first isolation material layer and the isolation material layer may be prepared in sequence firstly, then the second isolation material layer located in the upper layer is patterned to obtain the second isolation portion 22, and then the first isolation material layer located in the lower layer is patterned to obtain the first isolation portion 21.

In some optional embodiments, the step S4 of patterning the first encapsulation layer 50 and the second encapsulation layer 60 includes: etching the first encapsulation layer 50 and the second encapsulation layer 60 simultaneously, and making an etch rate of the second encapsulation layer 60 greater than an etch rate of the first encapsulation layer 50.

As described above, in the embodiments of the present application, two encapsulation layers are stacked, and after the two encapsulation layers being patterned, the area of the orthographic projection of the second encapsulation layer 60 is less than the area of the orthographic projection of the first encapsulation layer 50, so that the film layer structure formed in the subsequent process can cover the preset position. On this basis, in order to improve the processing efficiency and reduce the processing cost, the first encapsulation layer 50 and the second encapsulation layer 60 may be etched simultaneously in the step S4 of patterning the two encapsulation layers, and the difference between the etched areas are formed by the difference between the materials or internal structures of the first encapsulation layer 50 and the second encapsulation layer 60.

Specifically, in the step S3 of preparing the first encapsulation layer 50 and the second encapsulation layer 60, different materials may be used to form the two encapsulation layers, or a same material may be used to prepare film layers in which densities of internal structures are different. In an embodiment in which different materials are used, the material may be selected according to relevant process conditions such as the etching solution used for etching, a material with a relatively greater etch rate is used to form the second encapsulation layer 60, and a material with a relatively less etch rate is used to form the first encapsulation layer 50. In an embodiment in which a same material is used to form film layers with different densities, the internal structure of the film layer of the first encapsulation layer 50 may be denser, while the internal structure of the film layer of the second encapsulation layer 60 may be looser, which also enables the second encapsulation layer 60 to have a greater etch rate.

On this basis, in the patterning process of the step S4, the second encapsulation layer 60 can have a greater etch rate. That is, in a same etching process, in a same period of time, the size of the area of the second encapsulation layer 60 removed by etching should be greater than the size of the area of the first encapsulation layer 50 removed by etching. Therefore, the encapsulation layer structures with different areas of orthographic projection can be obtained in the same patterning process, which avoids the reduction of production efficiency caused by multiple etchings.

Optionally, in an embodiment in which a same material is used to form film layers with different densities, the density of the internal structure of the film layer may be determined according to the refractive index of the film layer. The higher the refractive index, the denser the structure, and the less the etch rate; on the contrary, the lower the refractive index, the looser the structure, and the greater the etch rate.

In some optional embodiments, a thickness of the first encapsulation layer 50 is greater than or equal to a thickness of the second encapsulation layer 60. In the step S4 of preparing the double-layer encapsulation layer, the thickness of the two encapsulation layers may be adjusted, so that the first encapsulation layer 50 located in the lower layer has a relatively greater thickness, so as to further increase the etch rate difference between the two encapsulation layers when the encapsulation layers are patterned, thereby forming the desired trapezoid-like structure more quickly.

In some optional embodiments, the step S4 of patterning the first encapsulation layer 50 and the second encapsulation layer 60 includes: arranging a photoresist layer at a side of the second encapsulation layer 60 away from the first encapsulation layer 50; and performing exposure, development, and etching on the first encapsulation layer 50 and the second encapsulation layer 60 to form a first encapsulation sub-layer and a second encapsulation sub-layer, the first encapsulation sub-layer and the second encapsulation sub-layer being stacked and forming a plurality of first sub-encapsulation portions 51, and in the thickness direction X, the first sub-encapsulation portions 51 being in one-to-one correspondence with the first sub-pixels 112 and arranged covering the first sub-pixels 112.

In the method for manufacturing a display panel 100 according to the embodiments of the present application, the two encapsulation layers are patterned in the step S4, and the patterning may be performed using photolithography. The photoresist layer is first coated on the outer side, i.e., the side of the second encapsulation layer 60 away from the first encapsulation layer 50, and then exposed and developed to cover the preset position. On this basis, etching is performed to form the encapsulation layer with a desired shape. In such cases, the patterned encapsulation layer may form a plurality of first sub-encapsulation portions 51 which are independent of each other and in one-to-one correspondence with the first sub-pixels 112, and each first sub-encapsulation portion 51 constitutes an encapsulation structure for the underlying first sub-pixel 112, so as to prevent water vapor invasion.

In such cases, the isolation structure 20 is arranged between any adjacent first sub-encapsulation portions 51 and can form a barrier to water vapor between the first sub-encapsulation portions 51, so that the path for water vapor invasion at the position of a certain first sub-pixel 112 can be extended, so as to prevent the oxidation failure from spreading to the peripheral pixels, and thus the reliability of the display panel 100 can be effectively increased.

In some optional embodiments, performing exposure, development, and etching on the first encapsulation layer 50 and the second encapsulation layer 60 to form the first sub-encapsulation portions 51 includes: making an orthographic projection of the first sub-encapsulation portion 51 at least partially overlaps the isolation structure 20 along the thickness direction X.

The first sub-encapsulation portion 51 in the embodiments of the present application is consist of the first encapsulation layer 50 and the second encapsulation layer 60 that are stacked, the etched first sub-encapsulation portion 51 may be at least partially connected with the isolation structure 20. In such cases, the orthographic projection of the first sub-encapsulation portion 51 in the thickness direction X may at least partially overlap the orthographic projection of the isolation structure 20 in the direction, so as to ensure a tight connection between the encapsulation structure and the peripheral isolation structure 20, thereby ensuring the reliability of pixel protection.

Optionally, in an embodiment in which the isolation structure 20 includes the first isolation portion 21 and the second isolation portion 22, it should be ensured that the spacing between the second encapsulation layer 60 located in the upper layer and the base plate 10 is greater than or equal to the spacing between the upper surface of the first isolation portion 21 and the base plate 10. That is, the stacked double-layer encapsulation structure should cover at least the under-cut portion of the isolation structure 20 and the side edge of the first isolation portion 21, so as to ensure that the formed encapsulation portion has a good encapsulation effect, and also a new chamfered recessed structure can be avoided at the interface between the first isolation portion 21 and the second isolation portion 22.

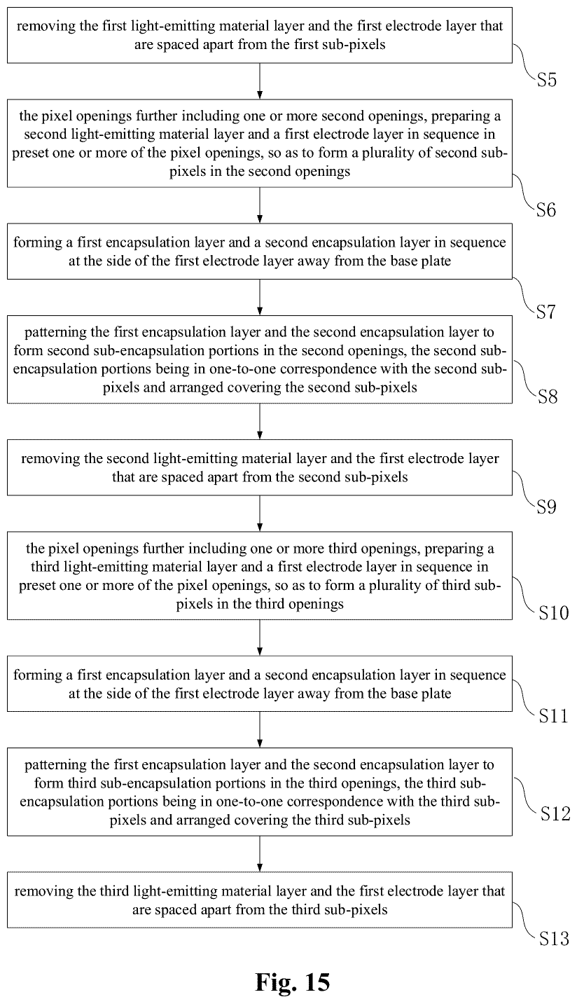

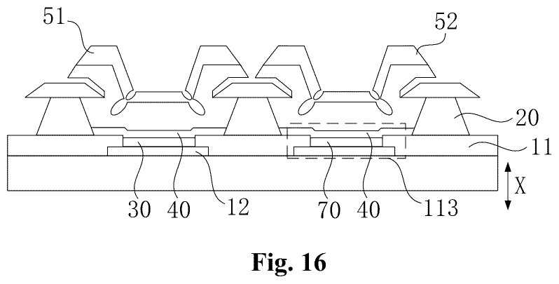

Referring to FIGS. 15 and 16, FIG. 15 shows a flowchart of a method for manufacturing a display panel according to yet another embodiment of the present application, and FIG. 16 shows a schematic structural diagram corresponding to step S9 of the method illustrated in FIG. 15. In some optional embodiments, the method further includes, after the step S4 of patterning the first encapsulation layer 50 and the second encapsulation layer 60:
S5: removing the first light-emitting material layer 30 and the first electrode layer 40 that are spaced apart from the first sub-pixels 112;
S6: the pixel openings 111 further include one or more second openings, preparing a second light-emitting material layer 70 and a first electrode layer 40 in sequence in preset one or more of the pixel openings 111, so as to form a plurality of second sub-pixels 113 in the second openings;
S7: forming a first encapsulation layer 50 and a second encapsulation layer 60 in sequence at the side of the first electrode layer away from the base plate;
S8: patterning the first encapsulation layer 50 and the second encapsulation layer 60 to form second sub-encapsulation portions 52 in the second openings, the second sub-encapsulation portions 52 being in one-to-one correspondence with the second sub-pixels 113 and arranged covering the second sub-pixels 113; and
S9: removing the second light-emitting material layer 70 and the first electrode layer 40 that are spaced apart from the second sub-pixels 113.

As described above, in the method for manufacturing the display panel 100 according to the embodiments of the present application, the pixels may be divided into a plurality of types of pixels according to the different colors of the pixels, i.e., according to the different organic light-emitting materials, and prepared in a plurality of batches. For example, after the first sub-pixel 112 and its encapsulation structure, i.e., the first sub-encapsulation portion 51, are prepared, a second sub-pixel 113 of another color may be prepared in a manner similar to the above preparation method of the first sub-pixel 112.

When the second sub-pixel 113 is processed, the first light-emitting material layer 30 and the corresponding first electrode layer 40 that are vapor deposited for preparing the first sub-pixel 112 should be first removed in step S5, so as to empty the pixel openings 111 in which the first sub-pixels 112 are not formed for accommodating the second light-emitting material layer 70 and forming light-emitting pixel structures of other colors, i.e., the second sub-pixels 113.

Subsequently, similar to the preparation of the first sub-pixel 112, the second light-emitting material layer 70, the first electrode layer 40, as well as the first encapsulation layer 50 and the second encapsulation layer 60 are prepared in sequence on the base plate 10 and the isolation structure 20 and patterned, and the encapsulation layer outside the area corresponding to the second sub-pixel 113 is etched and removed, so as to form the encapsulation structure of the second sub-pixel 113, i.e., the second sub-encapsulation portion 52. If other film layer structures should be prepared after the second sub-pixels 113 being processed, then in the thickness direction X, the area of the orthographic projection of the second encapsulation layer 60 in the second sub-encapsulation portion 52 may also be less than the area of the orthographic projection of the first encapsulation layer 50, with the same principle, it is ensured that various positions should be covered in the display panel 100 can be covered by film layers formed in other subsequent processes.

Moreover, similarly, after the second sub-pixels 113 being prepared, the second light-emitting material layer 70 and the first electrode layer 40 in the pixel openings 111 in which neither the first sub-pixel 112 nor the second sub-pixel 113 is arranged should also be removed, so as to facilitate forming other light-emitting material layers in the pixel openings 111 subsequently and continuing to prepare light-emitting pixels of a third color.

In some optional embodiments, the method further includes, after the step S9 of removing the second light-emitting material layer 70 and the first electrode layer 40 that are spaced apart from the second sub-pixels 113:
S10: the pixel openings 111 further including one or more third openings, preparing a third light-emitting material layer and a first electrode layer in sequence in preset one or more of the pixel openings 111, so as to form a plurality of third sub-pixels in the third openings;
S11: forming a first encapsulation layer 50 and a second encapsulation layer 60 in sequence at the side of the first electrode layer away from the base plate 10;
S12: patterning the first encapsulation layer 50 and the second encapsulation layer 60 to form third sub-encapsulation portions in the third openings, the third sub-encapsulation portions being in one-to-one correspondence with the third sub-pixels and arranged covering the third sub-pixels; and
S13: removing the third light-emitting material layer and the first electrode layer that are spaced apart from the third sub-pixels.

For example, the display panel 100 is an OLED panel that includes pixels of three colors, i.e., red, green, and blue. Similar to the preparation of the first sub-pixel 112 and the second sub-pixel 113, after the pixels of the second color are prepared, the above preparation and patterning process of the light-emitting material layer, the first electrode layer, the first encapsulation layer 50, and the second encapsulation layer 60 may be further repeated to form the third sub-pixels of the third color to achieve desired color display, and the specific preparation process is not repeated herein.

After the sub-pixels of the three colors fill all the pixel openings 111, it may be considered that the preparation of the light-emitting pixels is completed. In such cases, the display panel 100 includes a plurality of sub-pixels that are separated by the isolation structure 20 and thus independent of each other. Each sub-pixel is provided with an encapsulation portion, and the encapsulation portions may also be independent of each other due to the isolation structure 20, which can avoid crosstalk between the adjacent pixels and achieve independent control, and the like. The display panel consisting of R, G and B pixels is described as an example in the embodiments of the present application, but it should be understood that the present application is not limited thereto. The display panel 100 may consist of pixels of more or less colors, and any suitable color may be selected, as long as the desired display function can be achieved.

In some optional embodiments, the first encapsulation layer 50 and the second encapsulation layer 60 are made of an inorganic material, and the step of forming the first encapsulation layer 50 or the step of forming the second encapsulation layer 60 includes: performing the preparation using chemical vapor deposition.

In order to improve the protection effect against water vapor invasion, both the first encapsulation layer 50 and the second encapsulation layer 60 in the embodiments of the present application may be made of an inorganic material, so as to further improve the reliability of the display panel 100, and each of the two encapsulation layers may be prepared using Chemical Vapor Deposition (CVD).

CVD is a very common material deposition technology in the semiconductor industry. Using CVD to prepare an inorganic encapsulation layer can make the layer structure more uniform and reliable, and the requirement for process condition of CVD is low and the processing efficiency is high, which can increase the overall product yield and processing efficiency of the display panel 100.

What is claimed is:

1. A display panel, comprising:
a base plate comprising a pixel definition layer, the pixel definition layer comprising a plurality of pixel openings arranged at intervals;
an isolation structure arranged at a side of the base plate adjacent to the pixel definition layer, an orthographic projection of the isolation structure on the pixel definition layer being spaced apart from and surrounding the pixel openings;
a plurality of sub-pixels arranged in the pixel openings; and
an encapsulation structure arranged at a side of the sub-pixels opposite the base plate, the encapsulation structure comprising a plurality of sub-encapsulation portions, each sub-encapsulation portion comprising a first encapsulation sub-layer and a second encapsulation sub-layer, the first encapsulation sub-layer being arranged between the sub-pixel and the second encapsulation sub-layer, and in a thickness direction of the display panel, an area of an orthographic projection of the second encapsulation sub-layer being less than an area of an orthographic projection of the first encapsulation sub-layer.

2. The display panel according to claim 1, wherein along the thickness direction, the orthographic projection of the second encapsulation sub-layer is located within an outline of the orthographic projection of the first encapsulation sub-layer.

3. The display panel according to claim 1, wherein along a direction away from the base plate, the sub-pixel comprises a light-emitting material layer and a first electrode that are stacked in sequence, and the isolation structure is electrically connected to the first electrode.

4. The display panel according to claim 1, wherein the isolation structure comprises a first isolation portion and a second isolation portion, the second isolation portion being located at a side of the first isolation portion away from the base plate, and along the thickness direction, an area of an orthographic projection of the second isolation portion being greater than an area of an orthographic projection of the first isolation portion.

5. The display panel according to claim 1, wherein the isolation structure comprises a sidewall facing the pixel openings, and the sub-encapsulation portion is arranged to cover the sidewall.

6. The display panel according to claim 5, wherein the sub-encapsulation portion further extends to a side of the isolation structure away from the base plate, and a gap is formed between the sub-encapsulation portion and a surface of the isolation structure away from the base plate; or the sub-encapsulation portion further extends to a side of the isolation structure away from the base plate, and in the thickness direction, an orthographic projection of each sub-encapsulation portion overlaps the orthographic projection of the isolation structure, and a width of an overlapping area is less than a half of a width of the orthographic projection of the isolation structure.

7. The display panel according to claim 1, wherein an etch rate of the second encapsulation sub-layer is greater than an etch rate of the first encapsulation sub-layer.

8. The display panel according to claim 1, wherein a density of the second encapsulation sub-layer is less than a density of the first encapsulation sub-layer.

9. The display panel according to claim 1, wherein a refractive index of the second encapsulation sub-layer is less than a refractive index of the first encapsulation sub-layer.

10. The display panel according to claim 1, wherein a thickness of the first encapsulation sub-layer is greater than a thickness of the second encapsulation sub-layer.

11. The display panel according to claim 1, wherein along the thickness direction, the first encapsulation sub-layer comprises a first surface close to the base plate and a third surface away from the base plate, and along the thickness direction, an orthographic projection of the third surface is located within an outline of an orthographic projection of the first surface; or
along the thickness direction, the second encapsulation sub-layer includes a fourth surface close to the base plate and a second surface away from the base plate, and along the thickness direction, an orthographic projection of the second surface is located within an outline of an orthographic projection of the fourth surface.

12. The display panel according to claim 11, wherein along the thickness direction, the orthographic projection of the fourth surface is located within an outline of the orthographic projection of the third surface, or the outline of the orthographic projection of the fourth surface coincides with the outline of the orthographic projection of the third surface.

13. A display apparatus, comprising the display panel according to claim 1.

14. A method for manufacturing a display panel, comprising:
providing a base plate comprising a pixel definition layer, the pixel definition layer comprising a plurality of pixel openings arranged at intervals, the pixel openings comprising a plurality of first openings;
preparing an isolation structure at a first side of the pixel definition layer, an orthographic projection of the isolation structure on the pixel definition layer being spaced apart from the pixel openings and arranged around the pixel openings;
preparing a first light-emitting material layer and a first electrode layer in sequence in one or more of the pixel openings to form a plurality of first sub-pixels in the first openings;
forming a first encapsulation layer and a second encapsulation layer in sequence at a second side of the first electrode layer opposite the base plate; and
patterning the first encapsulation layer and the second encapsulation layer to respectively form a first encapsulation sub-layer and a second encapsulation sub-layer, such that in a thickness direction of the display panel, an area of an orthographic projection of the second encapsulation sub-layer is less than an area of an orthographic projection of the first encapsulation sub-layer.

15. The method according to claim 14, wherein the step of preparing the isolation structure comprises:
preparing a first isolation portion at the first side of the pixel definition layer; and
preparing a second isolation portion at a side of the first isolation portion away from the base plate, such that in the thickness direction, an area of an orthographic projection of the second isolation portion is greater than an area of an orthographic projection of the first isolation portion.

16. The method according to claim 14, wherein the step of patterning the first encapsulation layer and the second encapsulation layer comprises:
etching the first encapsulation layer and the second encapsulation layer simultaneously, wherein an etch rate of the second encapsulation layer is greater than an etch rate of the first encapsulation layer.

17. The method according to claim 16, wherein the step of patterning the first encapsulation layer and the second encapsulation layer comprises:
arranging a photoresist layer on a side of the second encapsulation layer opposite the first encapsulation layer; and
performing exposure, development, and etching on the first encapsulation layer and the second encapsulation layer to form a first encapsulation sub-layer and a second encapsulation sub-layer, the first and second encapsulation sub-layers being stacked and forming a plurality of first sub-encapsulation portions that correspond to and cover the first sub-pixels.

18. The method according to claim 17, wherein the orthographic projection of the first sub-encapsulation portion at least partially overlaps the isolation structure along the thickness direction.

19. The method according to claim 14, further comprising, after the step of patterning the first encapsulation layer and the second encapsulation layer:
removing the first light-emitting material layer and the first electrode layer from the pixel openings that do not contain the first sub-pixels;
preparing a second light-emitting material layer and a first electrode layer in sequence in one or more of the pixel openings, to form a plurality of second sub-pixels in the second openings;
forming a first encapsulation layer and a second encapsulation layer in sequence at a side of the first electrode layer opposite the base plate;
patterning the first encapsulation layer and the second encapsulation layer to form second sub-encapsulation portions in the second openings, the second sub-encapsulation portions being in one-to-one correspondence with the second sub-pixels and arranged covering the second sub-pixels; and
removing the second light-emitting material layer and the first electrode layer from the pixel openings that do not contain the second sub-pixels.

20. The method according to claim 19, further comprising, after removing the second light-emitting material layer and the first electrode layer from the pixel openings that do not contain the second sub-pixels:
preparing a third light-emitting material layer and a first electrode layer in sequence in one or more of the pixel openings, to form a plurality of third sub-pixels in the third openings;
forming a first encapsulation layer and a second encapsulation layer in sequence at a side of the first electrode layer opposite the base plate;
patterning the first encapsulation layer and the second encapsulation layer to form third sub-encapsulation portions in the third openings, the third sub-encapsulation portions being in one-to-one correspondence with the third sub-pixels and arranged covering the third sub-pixels; and
removing the third light-emitting material layer and the first electrode layer that are spaced apart from the third sub-pixels.
